(19) United States
(12) Patent Application Publication
(10) Pub. No.: US 2026/0101487 A1
(43) Pub. Date: Apr. 9, 2026

(54) THERMAL MANAGEMENT SYSTEM FOR A HYBRID ELECTRIC AIRCRAFT ENGINE

(71) Applicant: General Electric Aerospace Poland Sp. z o. o., Warsaw (PL)

(72) Inventors: Adam Tomasz Pazinski, Warsaw (PL); Victor Moreno, Queretaro (MX); Jeffrey Douglas Rambo, Mason, OH (US)

(21) Appl. No.: 18/907,039

(22) Filed: Oct. 4, 2024

(51) Int. Cl. H05K 7/20; B64D 27/33; B64D 33/08

(52) U.S. Cl. CPC H05K 7/20927; B64D 27/33; B64D 33/08

(57) ABSTRACT

A thermal management system for an aircraft engine includes a closed-loop fluid circuit including a coolant supply leg, a first electric power system leg, and a second electric power system leg. A coolant supply system is fluidly coupled to the coolant supply leg for providing a coolant fluid to the coolant supply leg, the first electric power system leg, and the second electric power system leg of the closed-loop fluid circuit. A flow control device fluidly couples the coolant supply system via the coolant supply leg, to the first electric power system leg, and to the second electric power system leg. A first heat source is in thermal communication with the coolant fluid via the first electric power system leg, and a second heat source is in thermal communication with the coolant fluid via the second electric power system leg.

### FIELD

The present disclosure relates to a thermal management system for electric machines which may be incorporated into an aeronautical gas turbine engine.

### BACKGROUND

Hybrid-electric propulsion systems are being developed to improve efficiency of conventional commercial aircraft. Some hybrid electric propulsion systems include one or more electric machines each being mechanically coupled with a rotating component of one of the aircraft engines. The electric machines can each have an associated power electronics assembly electrically connected thereto including a power converter and power distribution or management units. Thermal management becomes more complex as there are more tailored thermal needs for each of the various electronic components that convert and distribute power to the various electronic components or systems of the gas turbine engine or aircraft.

### BRIEF DESCRIPTION OF THE DRAWINGS

A full and enabling disclosure of the present disclosure, including the best mode thereof, directed to one of ordinary skill in the art, is set forth in the specification, which makes reference to the appended figures, in which:

FIG. 1 provides a schematic top view of an aircraft having a hybrid-electric propulsion system according to various exemplary embodiments of the present disclosure.

FIG. 2 provides a schematic cross-sectional view of one of the hybrid-electric propulsors of the aircraft of FIG. 1.

FIG. 3 provides a simplified, schematic view of a thermal management system in accordance with an exemplary aspect of the present disclosure.

FIG. 4 provides a simplified, schematic view of a portion of the thermal management system as shown in FIG. 3 including a coolant supply system, a flow control device, a valve controller, and a pump controller according to an exemplary embodiment of the present disclosure.

FIG. 5 provides a simplified, schematic view of a portion of the thermal management system as shown in FIG. 3 including a coolant supply system, a flow control device, a valve controller, and a pump controller according to an exemplary embodiment of the present disclosure.

FIG. 6 provides a simplified, schematic view of the thermal management system as shown in FIG. 3 in accordance with another exemplary aspect of the present disclosure.

FIG. 7 provides an example computing system according to example embodiments of the present disclosure.

FIG. 8 provides an exemplary graph illustrating a relationship between coolant flow rate, power need, and rotational engine speed according to one aspect of the present disclosure.

### DETAILED DESCRIPTION

Reference will now be made in detail to present embodiments of the disclosure, one or more examples of which are illustrated in the accompanying drawings. The detailed description uses numerical and letter designations to refer to features in the drawings. Like or similar designations in the drawings and description have been used to refer to like or similar parts of the disclosure.

The word “exemplary” is used herein to mean “serving as an example, instance, or illustration.” Any implementation described herein as “exemplary” is not necessarily to be construed as preferred or advantageous over other implementations. Additionally, unless specifically identified otherwise, all embodiments described herein should be considered exemplary.

As used herein, the terms “first”, “second”, and “third” may be used interchangeably to distinguish one component from another and are not intended to signify location or importance of the individual components.

The terms “forward” and “aft” refer to relative positions within a gas turbine engine or aircraft and refer to the normal operational attitude of the gas turbine engine or aircraft. For example, with regards to a gas turbine engine, forward refers to a position closer to an engine inlet and aft refers to a position closer to an engine nozzle or exhaust.

The terms “upstream” and “downstream” refer to the relative direction with respect to fluid flow in a fluid pathway. For example, “upstream” refers to the direction from which the fluid flows, and “downstream” refers to the direction to which the fluid flows.

The terms “coupled,” “fixed,” “attached to,” and the like refer to both direct coupling, fixing, or attaching, as well as indirect coupling, fixing, or attaching through one or more intermediate components or features, unless otherwise specified herein.

The singular forms “a”, “an”, and “the” include plural references unless the context clearly dictates otherwise.

Here and throughout the specification and claims, range limitations are combined and interchanged, such ranges are identified and include all the sub-ranges contained therein unless context or language indicates otherwise. For example, all ranges disclosed herein are inclusive of the endpoints, and the endpoints are independently combinable with each other.

It will be appreciated that as used herein, the terms “high/low-speed” and “high/low-pressure” are used with respect to the high-pressure/high-speed system of an aircraft engine and low-pressure/low-speed system of an aircraft engine interchangeably. Further, it will be appreciated that the terms “high” and “low” are used in this same context to distinguish between two systems and are not meant to imply any absolute speed and/or pressure values.

A “third stream” as used herein means a non-primary air stream capable of increasing fluid energy to produce a minority of total propulsion system thrust. A pressure ratio of the third stream may be higher than that of the primary propulsion stream (e.g., a bypass or propeller driven propulsion stream). The thrust may be produced through a dedicated nozzle or through mixing of an airflow through the third stream with a primary propulsion stream or a core air stream, e.g., into a common nozzle.

The following disclosure is directed to a singular thermal management system for cooling both high-pressure spool driven electric machines and associated electronic components and low-pressure spool driven electric machines and associated electronic components of an aircraft hybrid-electric propulsion system. The thermal management system includes a single coolant supply system which provides a cooled coolant fluid to both a first electric power system leg and a second electric power system leg of the thermal management system. The first electric power system leg provides thermal management for the electric machine and associated electronics (e.g., power converters and distribution electronic assemblies) associated with the high-pressure spool. The second electric power system leg provides thermal management for the electric machine and associated electronics (e.g., power converters and distribution electronic assemblies) associated with the low-pressure spool.

In exemplary embodiments, the thermal management system provided herein may provide heat rejection capacity sufficient to cool both the electric machine and associated electronics of the first electric power system leg at an operating point of at least 250KW and the electric machine and associated electronics of the second electric power system leg at an operating point of at least 150KW. In particular embodiments, the maximum total power of both the electric machine and associated electronics of the first electric power system leg and the electric machine and associated electronics of the second electric power system leg when combined/working together may not exceed more than 390KW. The thermal management system as provided herein may result in a lower demand on heat exchanger components of the single coolant supply system, thus improving component life and reducing weight of the overall thermal management system as compared to conventional solutions.

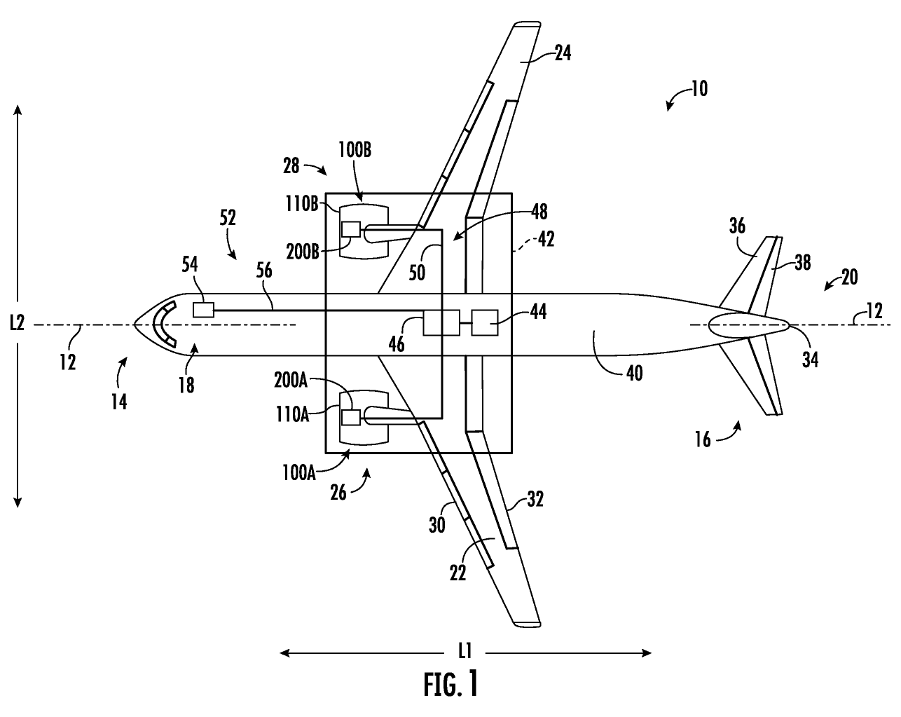

Referring now to the drawings, wherein identical numerals indicate the same elements throughout the figures, FIG. 1 provides a schematic top view of an exemplary aircraft 10 as may incorporate one or more aspects of the present disclosure. As shown in FIG. 1, for reference, the aircraft 10 defines a longitudinal direction L1 and a lateral direction L2. The lateral direction L2 is perpendicular to the longitudinal direction L1. The aircraft 10 also defines a longitudinal centerline 12 that extends therethrough along the longitudinal direction L1. The aircraft 10 extends between a forward end 14 and an aft end 16, e.g., along the longitudinal direction L1.

As depicted, the aircraft 10 includes a fuselage 18 that extends longitudinally from the forward end 14 of the aircraft 10 to the aft end 16 of the aircraft 10. The aircraft 10 also includes an empennage 20 at the aft end 16 of the aircraft 10. In addition, the aircraft 10 includes a wing assembly including a first wing 22 (e.g., a port side wing) and a second wing 24 (e.g., a starboard side wing). The first wing 22 and second wing 24 each extend laterally outward with respect to the longitudinal centerline 12. The first wing 22 and a portion of the fuselage 18 together define a first side 26 of the aircraft 10 and the second wing 24 and another portion of the fuselage 18 together define a second side 28 of the aircraft 10. For the embodiment depicted, the first side 26 of the aircraft 10 is configured as the port side of the aircraft 10 and the second side 28 of the aircraft 10 is configured as the starboard side of the aircraft 10.

The aircraft 10 includes various control surfaces. For this embodiment, each of the first wing 22 and the second wing 24 includes one or more leading edge flaps 30 and one or more trailing edge flaps 32. The aircraft 10 further includes, or more specifically, the empennage 20 of the aircraft 10 includes a vertical stabilizer 34 having a rudder flap (not shown) for yaw control and a pair of horizontal stabilizers 36 each having an elevator flap 38 for pitch control. The fuselage 18 additionally includes an outer surface or skin 40. It should be appreciated that in other exemplary embodiments of the present disclosure, the aircraft 10 may additionally or alternatively include any other suitable configuration. For example, in other embodiments, the aircraft 10 may include any other control surface configuration.

The exemplary aircraft 10 of FIG. 1 also includes a propulsion system 42. For example, in one embodiment, the propulsion system 42 may comprise of a hybrid-electric propulsion system. For this embodiment, the hybrid-electric propulsion system 42 has a first propulsor 100A and a second propulsor 100B both operable to produce thrust. The first propulsor 100A is mounted to the first wing 22 and the second propulsor 100B is mounted to the second wing 24. Moreover, for the embodiment depicted, the first propulsor 100A and second propulsor 100B are each configured in an underwing-mounted configuration. However, in other example embodiments, one or both of the first propulsor 100A and the second propulsor 100B may be mounted at any other suitable location in other exemplary embodiments.

The first propulsor 100A includes, for example, a gas turbine engine 110A and one or more electric machines, such as electric machine 200 mechanically coupled with the gas turbine engine 110A. The electric machine 200 can be an electric generator, an electric motor, or a combination generator/motor. For this example, embodiment, the electric machine 200 is a combination generator/motor. In this manner, when operating as an electric generator, the electric machine 200 can generate electrical power when driven by the gas turbine engine 110A. When operating as an electric motor, the electric machine 200 can drive or motor the gas turbine engine 110A.

Likewise, the second propulsor 100B includes, for example, a gas turbine engine 110B and one or more electric machines, such as electric machine 202 mechanically coupled with the gas turbine engine 110B. The electric machine 202 can be an electric generator, an electric motor, or a combination generator/motor. For this embodiment, the electric machine 202 is a combination generator/motor. In this manner, when operating as an electric generator, the electric machine 202 can generate electrical power when driven by gas turbine engine 110B. When operating as an electric motor, the electric machine 202 can drive or motor a spool of the gas turbine engine 110B. Electric machine 202 can be configured and can operate in a similar manner as electric machine 200 described herein.

The hybrid-electric propulsion system 42 further includes an electric energy storage unit 44 electrically connectable to the electric machines 200, 202, and in some embodiments, other electrical loads. In some exemplary embodiments, the electric energy storage unit 44 may include one or more batteries. Additionally, or alternatively, the electric energy storage units 44 may include one or more supercapacitor arrays, one or more ultracapacitor arrays, or both. For the hybrid-electric propulsion system 42 described herein, the electric energy storage unit 44 is configured to store a relatively large amount of electrical power. For example, in certain exemplary embodiments, the electric energy storage unit 44 may be configured to store at least about fifty kilowatt hours of electrical power, such as about seventy-five kilowatt hours of electrical power, and up to about one thousand kilowatt hours of electrical power.

The hybrid-electric propulsion system 42 also includes a power management system having a controller 46 and a power bus 48. The electric machines 200, 202, the electric energy storage unit 44, and the controller 46 are each electrically connectable to one another through one or more electric lines 50 of the power bus 48.

The controller 46 is configured to control the power electronics to distribute electrical power between the various components of the hybrid-electric propulsion system 42. For example, the controller 46 may control the power electronics of the power bus 48 (FIG. 1) to provide electrical power to, or draw electrical power from, the various components, such as the electric machines 200, 202, to operate the hybrid-electric propulsion system 42 between various operating modes and perform various functions. Such is depicted schematically as the electric lines 50 of the power bus 48 extend through the controller 46.

The controller 46 can form a part of a computing system 52 of the aircraft 10. The computing system 52 of the aircraft 10 can include one or more processors and one or more memory devices embodied in one or more computing devices. For instance, as depicted in FIG. 1, the computing system 52 includes controller 46 as well as other computing devices, such as computing device 54. The computing system 52 can include other computing devices as well, such as engine controllers (not shown). The computing devices of the computing system 52 can be communicatively coupled with one another via a communication network. For instance, computing device 54 is located in the cockpit of the aircraft 10 and is communicatively coupled with the controller 46 of the hybrid-electric propulsion system 42 via a communication link 56 of the communication network. The communication link 56 can include one or more wired or wireless communication links.

For this embodiment, the computing device 54 is configured to receive and process inputs, e.g., from a pilot or other crew members, and/or other information. In this manner, as one example, the one or more processors of the computing device 54 can receive an input indicating a command to change a thrust output of either or both the first propulsor 100A or the second propulsor 100B, and can cause, in response to the input, the controller 46 to control the electrical power drawn from or delivered to one or both of the electric machines 200, 202 to ultimately change the thrust output of one or both of the first propulsor 100A or the second propulsor 100B.

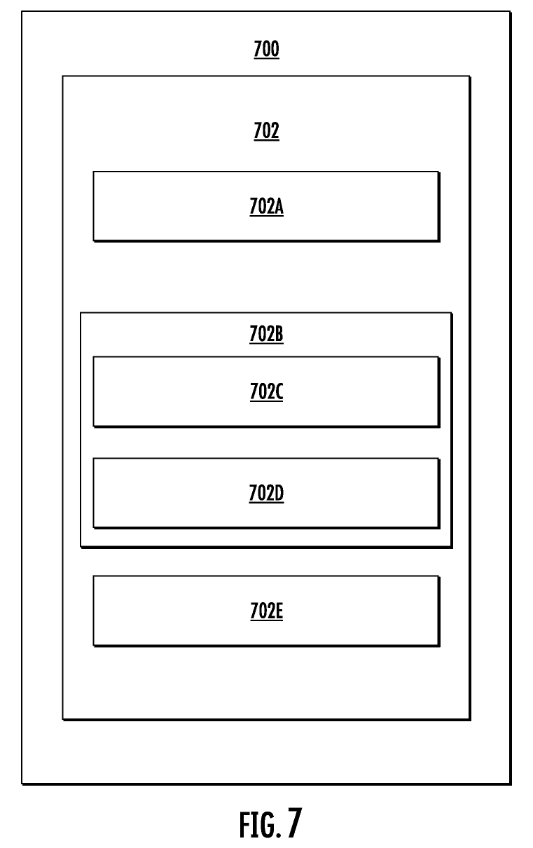

The controller 46 and other computing devices of the computing system 52 of the aircraft 10 may be configured in substantially the same manner as the exemplary computing devices of the computing system 700 described below with reference to FIG. 7.

It will be appreciated that the electric machines 200, 202, electric energy storage unit 44, and power management system (having the controller 46 and the power bus 48) may more specifically be configured as part of an aeronautical power system integrated with the gas turbine engines of the hybrid-electric propulsion system 42.

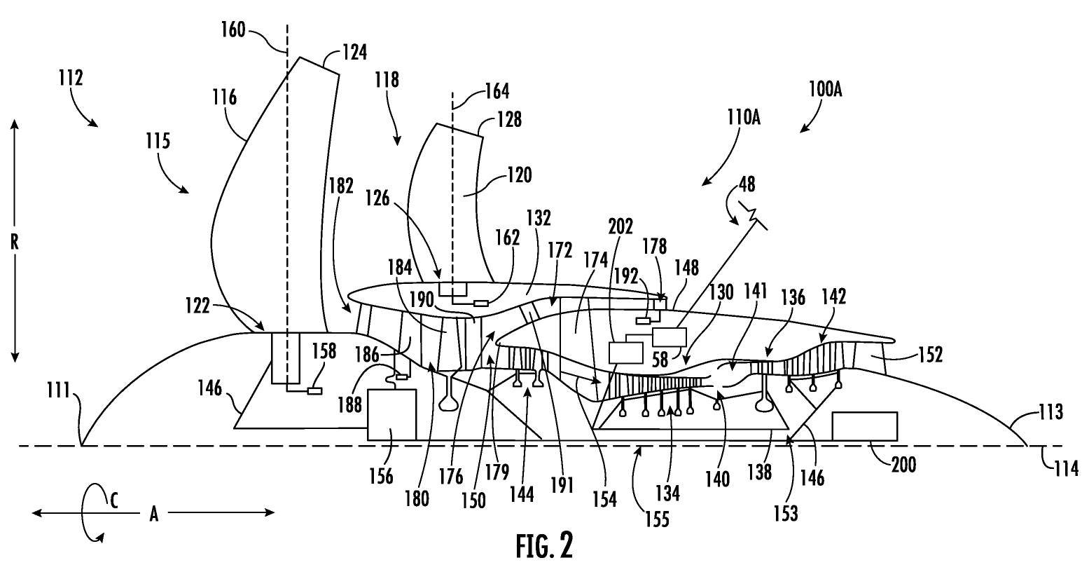

FIG. 2 provides a schematic view of the first propulsor 100A of the hybrid-electric propulsion system 42 of the aircraft 10 of FIG. 1. Although the first propulsor 100A is shown, it will be appreciated that the second propulsor 100B can be configured in the same or similar manner as the first propulsor 100A depicted in FIG. 2. The gas turbine engine 110A of FIG. 2 is configured as a “single unducted rotor” gas turbine engine 110A with a single stage of unducted rotor blades. In such a manner, the rotor assembly may be referred to herein as an “unducted fan,” or the gas turbine engine 110A may be referred to as an “unducted turbofan engine.” In addition, the gas turbine engine 110A of FIG. 2 includes a third stream extending from the compressor section to a rotor assembly flowpath over the turbomachine, as will be explained in more detail below. It should be understood that embodiments of the present disclosure are also applicable to other types of engines such as, by way of non-limiting examples, a ducted gas turbine engine, a ram-jet, or other gas turbines.

For reference, the gas turbine engine 110A defines an axial direction A, a radial direction R, and a circumferential direction C. Moreover, the gas turbine engine 110A defines an axial centerline or longitudinal axis 114 that extends along the axial direction A. In general, the axial direction A extends parallel to the longitudinal axis 114, the radial direction R extends outward from and inward to the longitudinal axis 114 in a direction orthogonal to the axial direction A, and the circumferential direction extends three hundred sixty degrees (360°) around the longitudinal axis 114. The gas turbine engine 110A extends between a forward end 111 and an aft end 113, e.g., along the axial direction A.

The gas turbine engine 110A includes a turbomachine 130 and a rotor assembly 112, also referred to as a fan section, positioned upstream thereof. Generally, the turbomachine 130 includes, in serial flow order, a compressor section, a combustion section, a turbine section, and an exhaust section. Particularly, as shown in FIG. 2, the turbomachine 130 includes a core cowl 148 that defines an annular core inlet 150. The core cowl 148 further encloses, at least in part, a low-speed or low-pressure system and a high-speed or high-pressure system. For example, the core cowl 148 depicted encloses and supports, at least in part, a booster or low-speed or low-pressure compressor 144 for pressurizing the air that enters the turbomachine 130 through annular core inlet 150. A high-speed or high-pressure, multi-stage, axial-flow compressor (referred to herein as a high-pressure compressor 134) receives pressurized air from the low-pressure compressor 144 and further increases the pressure of the air. The pressurized air stream flows downstream to a combustor 140 of the combustion section where fuel is injected into the pressurized air stream and ignited to raise the temperature and energy level of the pressurized air.

It will be appreciated that as used herein, the terms “high/low-speed” and “high/low-pressure” are used with respect to the high-pressure/high-speed system and low-pressure/low-speed system interchangeably. Further, it will be appreciated that the terms “high” and “low” are used in this same context to distinguish the two systems and are not meant to imply any absolute speed and/or pressure values.

The high energy combustion products flow from the combustor 140 downstream to a high-pressure turbine 136. The high-pressure turbine 136 drives the high-pressure compressor 134 through a high-pressure shaft 138. In this regard, the high-pressure turbine 136 is drivingly coupled with the high-pressure compressor 134. The high-pressure compressor 134, the high-pressure turbine 136, and the high-pressure shaft 138 may collectively be referred to as a high-speed or high-speed spool 153 of the gas turbine engine 110A. The high energy combustion products then flow to a low-pressure turbine 142. The low-pressure turbine 142 drives the low-pressure compressor 144 and components of the rotor assembly 112 through a low-pressure shaft 146. In this regard, the low-pressure turbine 142 is drivingly coupled with the low-pressure compressor 144 and components of the rotor assembly 112. The low-pressure compressor 144, the low-pressure turbine 142, and the low-pressure shaft 146 may collectively be referred to as a low-speed or low-speed spool 155 of the gas turbine engine 110A. The low-pressure shaft 146 is coaxial with the high-pressure shaft 138 in this example embodiment. After driving each of the high-pressure turbine 136 and the low-pressure turbine 142, the combustion products exit the turbomachine 130 through a turbomachine exhaust nozzle 152.

Accordingly, the turbomachine 130 defines a working gas flowpath or core duct 141 that extends between the annular core inlet 150 and the turbomachine exhaust nozzle 152. The core duct 141 is an annular duct positioned generally inward of the core cowl 148 along the radial direction R. The core duct 141 (e.g., the working gas flowpath through the turbomachine 130) may be referred to as a second stream.

The rotor assembly 112 includes a fan 115, which is the primary fan in this example embodiment. For the depicted embodiment of FIG. 2, the fan 115 is an open rotor or unducted fan. In such a manner, the gas turbine engine 110A may be referred to as an open rotor engine. However, it should be understood that embodiments of the present disclosure are also applicable to other types of engines such as, by way of non-limiting example, a ducted gas turbine engine.

As depicted, the fan 115 includes an array of airfoils arranged around the longitudinal axis 114 of the gas turbine engine 110A, and more particularly includes an array of fan blades 116 (only one shown in FIG. 2) arranged around the longitudinal axis 114 of the gas turbine engine 110A. The fan blades 116 are rotatable, e.g., about the longitudinal axis 114. As noted above, the fan 115 is drivingly coupled with the low-pressure turbine 142 via the low-pressure shaft 146. For the embodiments shown in FIG. 2, the fan 115 is coupled with the low-pressure shaft 146 via a power or speed reduction gearbox 156, e.g., in an indirect-drive or geared-drive configuration.

Moreover, the array of fan blades 116 can be arranged in equal spacing around the longitudinal axis 114. Each fan blade 116 has a proximal end or root 122 and a distal end or tip 124, with respect to the longitudinal axis 114, and a span defined therebetween. Each fan blade 116 defines a pitch change or central blade axis 160. For this embodiment, each fan blade 116 of the rotor assembly 112 is rotatable about its central blade axis 160, e.g., in unison with one another. A pitch change mechanism 158 in the form or one or more actuators is provided to facilitate such rotation and therefore may be used to change a pitch of the fan blades 116 about their respective central blade axis 160.

An array of airfoils positioned aft of the fan blades 116 is disposed around longitudinal axis 114, and more particularly includes a fan guide vane assembly 118 that includes fan guide vanes 120 (only one shown in FIG. 2) disposed around the longitudinal axis 114. For this embodiment, the fan guide vanes 120 are not rotatable about the longitudinal axis 114. Each fan guide vane 120 has a proximal end or root 126 and a distal end or tip 128, with respect to the longitudinal axis 114, and a span defined therebetween. The fan guide vanes 120 may be unshrouded as shown in FIG. 2 or, alternatively, may be shrouded, e.g., by an annular shroud spaced outward from the tips of the fan guide vanes 120 along the radial direction R or attached to the fan guide vanes 120.

Each fan guide vane 120 defines a central guide vane axis 164. For this embodiment, each fan guide vane 120 of the fan guide vane assembly 118 is rotatable about its respective central guide vane axis 164, e.g., in unison with one another. One or more pitch change mechanisms 162 in the form of one or more actuators are provided to facilitate such rotation and therefore may be used to change a pitch of the fan guide vane 120 about its respective central guide vane axis 164. However, in other embodiments, each fan guide vane 120 may be fixed or unable to be pitched about its central guide vane axis 164. The fan guide vanes 120 are mounted to a fan cowl 132.

As shown in FIG. 2, in addition to the fan 115, which is unducted, a ducted fan 184 is included aft of the fan 115, such that the gas turbine engine 110A includes both a ducted and an unducted fan which both serve to generate thrust through the movement of air without passage through at least a portion of the turbomachine 130 (e.g., without passage through the high-pressure compressor 134 and combustion section for the embodiment depicted). The ducted fan 184 is rotatable about the same axis (e.g., the longitudinal axis 114) as the fan blade 116. The ducted fan 184 is, for the embodiment depicted, driven by the low-pressure turbine 142 (e.g. coupled to the low-pressure shaft 146). In the embodiment depicted, as noted above, the fan 115 may be referred to as the primary fan, and the ducted fan 184 may be referred to as a secondary fan. It will be appreciated that these terms “primary” and “secondary” are terms of convenience, and do not imply any particular importance, power, or the like.

The ducted fan 184 includes a plurality of fan blades (not separately labeled in FIG. 2) arranged in a single stage, such that the ducted fan 184 may be referred to as a single stage fan. The fan blades of the ducted fan 184 can be arranged in equal spacing around the longitudinal axis 114. Each blade of the ducted fan 184 has a proximal end or root and a distal end or tip and a span defined therebetween.

The fan cowl 132 annularly encases at least a portion of the core cowl 148 and is generally positioned outward of at least a portion of the core cowl 148 along the radial direction R. Particularly, a downstream section of the fan cowl 132 extends over a forward portion of the core cowl 148 to define a fan duct flowpath, or simply a fan duct 172. According to this embodiment, the fan flowpath or fan duct 172 may be understood as forming at least a portion of the third stream of the gas turbine engine 110A.

Incoming air may enter through the fan duct 172 through a fan duct inlet 176 and may exit through a fan exhaust nozzle 178 to produce propulsive thrust. The fan duct 172 is an annular duct positioned generally outward of the core duct 141 along the radial direction R. The fan cowl 132 and the core cowl 148 are connected together and supported by a plurality of substantially radially extending and circumferentially spaced stationary struts 174 (only one shown in FIG. 2). The stationary struts 174 may each be aerodynamically contoured to direct air flowing thereby. Other struts in addition to the stationary struts 174 may be used to connect and support the fan cowl 132, the core cowl 148, or both. In many embodiments, the fan duct 172 and the core duct 141 may at least partially co-extend (generally axially) on opposite sides (e.g., opposite radial sides) of the core cowl 148. For example, the fan duct 172 and the core duct 141 may each extend directly from a leading edge 179 of the core cowl 148 and may partially co-extend generally axially on opposite radial sides of the core cowl 148.

The gas turbine engine 110A also defines or includes an inlet duct 180. The inlet duct 180 extends between an engine inlet 182 and the annular core inlet 150 and fan duct inlet 176. The engine inlet 182 is defined generally at the forward end of the fan cowl 132 and is positioned between the fan 115 and the fan guide vane assembly 118 along the axial direction A. The inlet duct 180 is an annular duct that is positioned inward of the fan cowl 132 along the radial direction R. Air flowing downstream along the inlet duct 180 is split, not necessarily evenly, into the core duct 141 and the fan duct 172 by a fan duct splitter or the leading edge 179 of the core cowl 148. In the embodiment depicted, the inlet duct 180 is wider than the core duct 141 along the radial direction R. The inlet duct 180 is also wider than the fan duct 172 along the radial direction R.

Notably, for the embodiment depicted, the gas turbine engine 110A includes one or more features to increase an efficiency of a third stream thrust, Fn_{3S} (e.g., a thrust generated by an airflow through the fan duct 172 exiting through the fan exhaust nozzle 178, generated at least in part by the ducted fan 184). In particular, the gas turbine engine 110A further includes an array of inlet guide vanes 186 positioned in the inlet duct 180 upstream of the ducted fan 184 and downstream of the annular core inlet 150. The array of inlet guide vanes 186 are arranged around the longitudinal axis 114. For this embodiment, the inlet guide vanes 186 are not rotatable about the longitudinal axis 114. Each inlet guide vane 186 defines a central blade axis (not labeled for clarity), and is rotatable about its respective central blade axis, e.g., in unison with one another. In such a manner, the inlet guide vanes 186 may be considered a variable geometry component. One or more actuators 188 are provided to facilitate such rotation and therefore may be used to change the pitch of the inlet guide vanes 186 about their respective central blade axes. However, in other embodiments, each inlet guide vane 186 may be fixed or unable to be pitched about its central blade axis.

Further, located downstream of the ducted fan 184 and upstream of the fan duct inlet 176, the gas turbine engine 110A includes an array of outlet guide vanes 190. As with the array of inlet guide vanes 186, the array of outlet guide vanes 190 are not rotatable about the longitudinal axis 114. However, for the embodiment depicted, unlike the array of inlet guide vanes 186, the array of outlet guide vanes 190 are configured as fixed-pitch outlet guide vanes.

Further, it will be appreciated that for the embodiment depicted, the fan exhaust nozzle 178 of the fan duct 172 is further configured as a variable geometry fan exhaust nozzle. In such a manner, the gas turbine engine 110A includes one or more actuators 192 for modulating the fan exhaust nozzle 178. For example, the fan exhaust nozzle 178 may be configured to vary a total cross-sectional area (e.g., an area of the nozzle in a plane perpendicular to the longitudinal axis 114) to modulate an amount of thrust generated based on one or more engine operating conditions (e.g., temperature, pressure, mass flowrate, etc. of an airflow through the fan duct 172). A fixed geometry exhaust nozzle may also be adopted.

Moreover, referring still to FIG. 2, in exemplary embodiments, air passing through the fan duct 172 may be relatively cooler (e.g., lower temperature) than one or more fluids utilized in the turbomachine 130. In this way, one or more heat exchangers 191 may be positioned in thermal communication with the fan duct 172. For example, one or more heat exchangers 191 may be disposed within the fan duct 172 and utilized to cool one or more fluids from the core engine with the air passing through the fan duct 172, as a resource for removing heat from a fluid, e.g., compressor bleed air, oil or fuel.

Referring still to FIG. 2, as noted, the first propulsor 100A includes electric machine 200 operably coupled with a rotating component thereof. In this regard, the first propulsor 100A is an aeronautical hybrid-electric propulsion machine. Particularly, as shown in FIG. 2, the electric machine 200 is mechanically coupled with the low-speed spool 155 of the gas turbine engine 110A, and more particularly, the low-pressure shaft 146 of the low-speed spool 155. As depicted, the electric machine 200 is embedded within the core of the gas turbine engine 110A. Specifically, the electric machine 200 is positioned inward of the core duct 141 along the radial direction R. Moreover, for this embodiment, the electric machine 200 is positioned generally at the aft end of the gas turbine engine 110A and is at least partially overlapping with or aft of the low-pressure turbine 142 along the axial direction A.

However, in other exemplary embodiments, the electric machine 200 may be positioned at other suitable locations within the gas turbine engine 110A. For instance, in some embodiments, the electric machine 200 can be coupled with the low-speed spool 155 in other suitable locations. For instance, in some embodiments, the electric machine 200 can be positioned forward of the low-pressure compressor 144 along the axial direction A and inward of a turbomachinery flowpath 154 along the radial direction R. Further, as shown in FIG. 2, the electric machine 200 mechanically coupled with the low-pressure shaft 146 is electrically coupled with the power bus 48.

In addition, or alternatively to the gas turbine engine 110A having electric machine 200 coupled to the low-speed spool 155, in the embodiment depicted, the gas turbine engine 110A further includes an electric machine 202 mechanically coupled with the high-speed spool 153 of the gas turbine engine 110A, and more particularly, the high-pressure shaft 138 of the high-speed spool 153. As depicted in FIG. 2, the electric machine 202 is mechanically coupled with the high-pressure shaft 138 through a mechanical linkage. The electric machine 202 is positioned outward of the core duct 141 along the radial direction R and is positioned forward of the combustion section of the gas turbine engine 110A along the axial direction A.

However, in other exemplary embodiments, the electric machine 202 may be positioned at other suitable locations within the gas turbine engine 110A (e.g., inward of the core duct 141 along the radial direction R).

Like the electric machine 200 mechanically coupled with the low-speed spool 155, the electric machine 202 mechanically coupled with the high-speed spool 153 can be an electric motor operable to drive or motor the high-pressure shaft 138, e.g., during a starting operation of the gas turbine engine 110A. In other embodiments, the electric machine 202 can be an electric generator operable to convert mechanical energy into electrical energy. In this way, electrical power generated by the electric machine 202 can be directed to various engine and/or aircraft systems. In some embodiments, the electric machine 202 can be a motor/generator with dual functionality.

Further, as shown in FIG. 2, the electric machine 202 mechanically coupled with the high-pressure shaft 138 is also electrically coupled with the power bus 48. More specifically, the aeronautical power system may include a power electronics assembly 58 located between the electric machines 200, 202 and the power bus 48. The power electronics assembly 58 may comprise one or more power inverters, power controllers, or other types of electronic components in electric connection with one or more electric power loads, electric power sources, or both (e.g., of the engine or the aircraft, or both).

Additionally, or alternatively, in other exemplary embodiments, any other suitable gas turbine engine may be provided. For example, in other exemplary embodiments, the gas turbine engine may be a turboshaft engine, a turboprop engine, turbojet engine, etc. Moreover, for example, although the engine is depicted as a single unducted rotor engine, in other embodiments, the engine may include a multi-stage open rotor configuration, and aspects of the disclosure described hereinbelow may be incorporated therein.

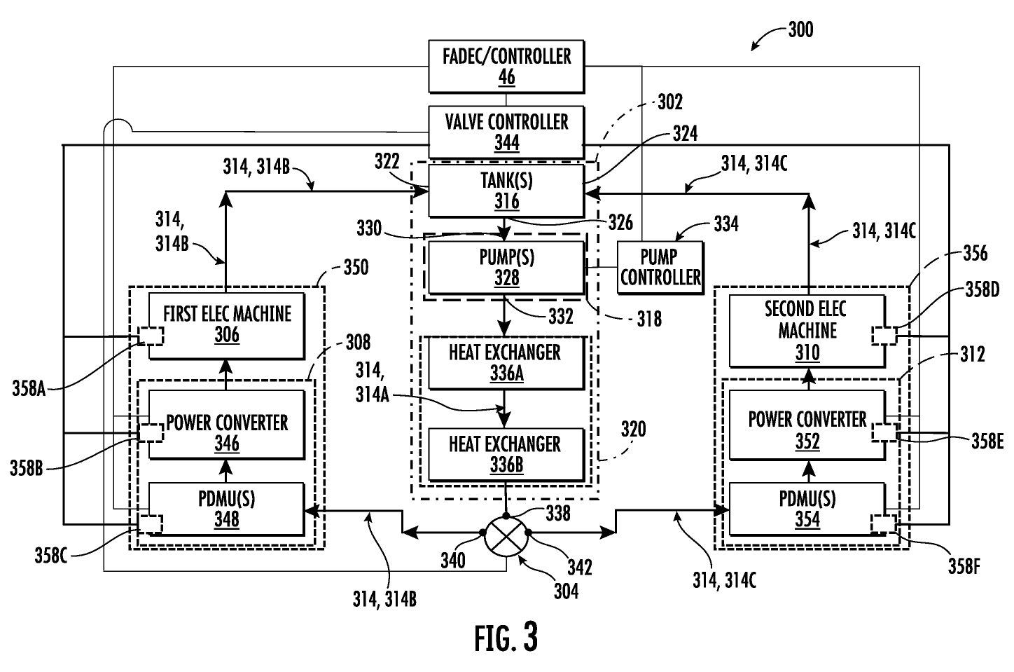

Referring now to FIG. 3, a simplified, schematic view is provided of a thermal management system 300 in accordance with an exemplary aspect of the present disclosure. The thermal management system 300 of FIG. 3 may be incorporated into one or more of the gas turbine engines 110A, 110B and/or aircraft 10 described herein, or in any other suitable engine and/or aircraft.

As shown in FIG. 3, the thermal management system 300 generally includes a coolant supply system 302, a flow control device 304, a first electric machine 306, a first power electronics assembly 308, a second electric machine 310, and a second power electronics assembly 312. The thermal management system 300 further includes or defines a closed-loop fluid circuit 314.

The closed-loop fluid circuit 314 is generally defined by one or more conduits, tubes, pipes, paths or passageways, walls, fluid couplings, or other structures for flowing a coolant fluid to, through, or both, the various components of the thermal management system 300.

In exemplary embodiments, as shown in FIG. 3, the closed-loop fluid circuit 314 includes a coolant supply leg 314A, a first electric power system leg 314B, and a second electric power system leg 314C. The coolant fluid can be of a suitable temperature for thermal energy transfer for a desired or particular function corresponding to the components of the thermal management system 300. In exemplary embodiments, the coolant fluid comprises oil. However, it should be understood that the fluid flowing via the closed-loop fluid circuit 314 may comprise any suitable coolant fluid for thermal energy transfer such as, by way of non-limiting examples, supercritical gases (e.g., carbon dioxide (CO₂), nitrogen (N₂), Helium (He), Xenon (Xe), and other gaseous mixtures), ethylene glycol, propylene glycol, Dow Corning’s Syltherm^{TM}, or Exxon Mobil’s Coolanol^{TM}.

In the exemplary embodiment shown in FIG. 3, the coolant supply system 302 generally includes a coolant tank 316, a pump assembly 318, and a heat exchanger assembly 320. In exemplary embodiments, the coolant tank 316, the pump assembly 318, and the flow control device 304 are arranged in serial flow order along the coolant supply leg 314A. For example, various conduits that form at least a portion of the coolant supply leg 314A of the closed-loop fluid circuit 314 fluidly couple the coolant tank 316 to the pump assembly 318, and the pump assembly 318 to the flow control device 304.

The coolant tank 316 may generally include a first tank inlet 322, a second tank inlet 324, and a tank outlet 326. In the illustrated embodiment, the pump assembly 318 includes a fluid pump 328. It is to be appreciated that in other embodiments, the pump assembly 318 may include a plurality of fluid pumps. The fluid pump 328 may be an electric pump or a mechanical pump. The pump assembly 318, particularly the fluid pump 328, includes a pump inlet 330 and a pump outlet 332. The pump assembly 318, particularly the fluid pump 328, may be electronically/operably coupled to a pump controller 334. The pump controller 334 may be configured to control flowrate of the coolant fluid, via the fluid pump 328 of the pump assembly 318, through the closed-loop fluid circuit 314 of the thermal management system 300.

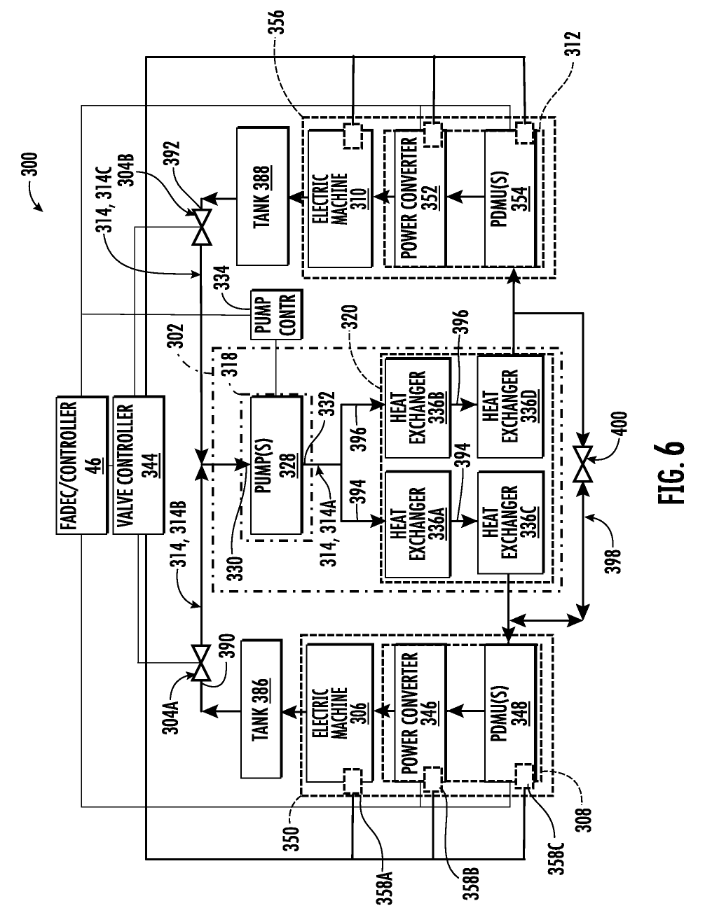

As shown in FIG. 3, the heat exchanger assembly 320 is disposed downstream from the pump assembly 318, more particularly downstream from the pump outlet 332, and upstream from the flow control device 304. The heat exchanger assembly 320 includes at least one heat exchanger. For example, the embodiment shown in FIG. 3 includes a first heat exchanger 336A and a second heat exchanger 336B. The first heat exchanger 336A and the second heat exchanger 336B may be arranged in series or in serial flow order along the coolant supply leg 314A of the closed-loop fluid circuit 314, or in alternate embodiments, may be arranged in parallel as shown in FIG. 6. As shown in FIG. 3, the heat exchanger assembly 320, or more particularly, the first heat exchanger 336A and the second heat exchanger 336B, is in thermal communication with (or thermally connected to) the coolant fluid via the coolant supply leg 314A of the closed-loop fluid circuit 314 downstream from the pump assembly 318, and upstream from the flow control device 304, the first electric power system leg 314B, and the second electric power system leg 314C.

The heat exchanger assembly 320, particularly one or both of the first heat exchanger 336A and the second heat exchanger 336B, may be located in the fan duct 172 (FIG. 2), such as the heat exchanger 191 (FIG. 2), exposed to overboard air, located in within the core cowl 148 (FIG. 2), or elsewhere within the gas turbine engine 110A (FIGS. 1 and 2). The first heat exchanger 336A and the second heat exchanger 336B could be gas-gas, gas-liquid, liquid-liquid heat exchangers or thermoelectric devices. Heat sink fluid associated with the first heat exchanger 336A and the second heat exchanger 336B could be fuel, water, water from an aircraft lavatory system, refrigerant from an environmental control system of an aircraft, or other suitable thermal transfer fluid.

In exemplary embodiments, the flow control device 304 may include a valve such as a multi-way valve or flow splitter as shown in FIG. 3 or may include a check valve or any other valve suitable for controlling flow through the closed-loop fluid circuit 314. In the embodiment illustrated in FIG. 3, the flow control device 304 is a flow splitter or multi-way valve and generally includes a valve inlet 338, a first valve outlet 340, and a second valve outlet 342. The valve inlet 338 is fluidly coupled to the coolant supply leg 314A of the closed-loop fluid circuit 314 downstream from the pump assembly 318. The first valve outlet 340 is fluidly coupled to the first tank inlet 322 via the first electric power system leg 314B of the closed-loop fluid circuit 314. The second valve outlet 342 is fluidly coupled to the second tank inlet 324 via the second electric power system leg 314C of the closed-loop fluid circuit 314. In this configuration, the coolant supply leg 314A, the flow control device 304, the first electric power system leg 314B, and the second electric power system leg 314C form or define the closed-loop fluid circuit 314.

In exemplary embodiments, the flow control device 304 is electronically connected to a valve controller 344. The valve controller 344 may be configured to control flowrate of the coolant fluid flowing from the coolant supply system 302 (e.g., flowing from the coolant supply leg 314A) to the first electric power system leg 314B and the second electric power system leg 314C. In other embodiments, the flow control device 304 may include or comprise of one or more passively controlled thermostatic valve(s) configured to passively control flowrate of the coolant fluid flowing from the coolant supply system 302 (e.g., flowing from the coolant supply leg 314A) to the first electric power system leg 314B and the second electric power system leg 314C. For example, the flow control device 304 may include a first thermostatic valve coupled to the first valve outlet 340. In addition, or in the alternative, the flow control device 304 may include a second thermostatic valve fluidly coupled to the second valve outlet 342.

The first electric machine 306 is thermally connected to and in thermal communication with the first electric power system leg 314B of the closed-loop fluid circuit 314. The first electric machine 306 may be rotatable with a first rotating component of an engine when the thermal management system 300 is integrated with the engine. For example, in certain exemplary embodiments, the first electric machine 306 may be rotatable with the high-speed spool 153 of the gas turbine engine 110A shown in FIG. 2. The first electric machine 306 can be an electric generator, an electric motor, or a combination generator/motor. For this exemplary embodiment, the first electric machine 306 is a combination generator/motor. In this manner, when operating as an electric generator, the first electric machine 306 can generate electrical power when driven by the high-speed spool 153 of the gas turbine engine 110A. When operating as an electric motor, the first electric machine 306 can drive or motor the gas turbine engine 110A.

Referring still to FIG. 3, the first power electronics assembly 308 is electrically connected to the first electric machine 306. The first power electronics assembly 308 is thermally connected to and in thermal communication with the coolant fluid via the first electric power system leg 314B of the closed-loop fluid circuit 314. In exemplary embodiments, the first power electronics assembly 308 may comprise the power electronics assembly 58 incorporated into one or more of the gas turbine engines 110A, 110B, aircraft 10, or both (FIGS. 1 and 2).

The first power electronics assembly 308 may comprise one or more power converters 346 (e.g., a first power convertor, a second power convertor, etc.) and one or more power controllers, and more specifically, one or more power distribution and monitoring units (referred to herein as a “PDMU(s) 348”), in electric connection with the one or more power converters 346, as well as with one or more electric power loads, electric power sources, or both (e.g., of the engine or the aircraft, or both). In such a manner, the one or more PDMU(s) 348 may receive electric power from the one or more power converters 346 and may distribute the electric power to one or more electric power loads of the engine and the aircraft, e.g., in response to one or more commands or other data inputs. Collectively, the first electric machine 306 and the first power electronics assembly 308 may act or serve as a first heat source 350 for providing thermal energy or heat to the coolant fluid flowing through the first electric power system leg 314B of the thermal management system 300.

Of course, in other embodiments, the directional flow of electric power may be reversed. It will be appreciated that the PDMU(s) 348 may include a computing device(s) configured in substantially the same manner as the exemplary computing devices of the computing system 700 described below with reference to FIG. 7. In such a manner, the PDMU(s) 348 may be configured to receive one or more data inputs and may make control decisions in response to the one or more data inputs.

As further illustrated in FIG. 3, the second electric machine 310 is thermally connected to and in thermal communication with the second electric power system leg 314C of the closed-loop fluid circuit 314. The second electric machine 310 may be rotatable with a second rotating component of an engine when the thermal management system 300 is integrated with gas turbine engine 110A, 110B. For example, in certain exemplary embodiments, the second electric machine 310 may be rotatable with the low-speed spool 155 of the gas turbine engine 110A shown in FIG. 2. The second electric machine 310 can be an electric generator, an electric motor, or a combination generator/motor. For this embodiment, the second electric machine 310 is a combination generator/motor. In this manner, when operating as an electric generator, the second electric machine 310 can generate electrical power when driven by the gas turbine engine 110A. When operating as an electric motor, the second electric machine 310 can drive or motor the gas turbine engine 110A, 110B.

Referring still to FIG. 3, the second power electronics assembly 312 is electrically connected to the second electric machine 310. The second power electronics assembly 312 is thermally connected to and in thermal communication with the coolant fluid via the second electric power system leg 314C of the closed-loop fluid circuit 314. The second power electronics assembly 312 may be incorporated into one or more of the gas turbine engines 110A, 110B, aircraft 10, or both (FIGS. 1 and 2). The second power electronics assembly 312 may comprise one or more power converters 352 and one or more power controllers, and more specifically, one or more power distribution and monitoring units (referred to herein as a “PDMU(s) 354”), in electric connection with the one or more power converters 352, as well as with one or more electric power loads, electric power sources, or both (e.g., of the engine or the aircraft, or both). In such a manner, the one or more PDMU(s) 354 may receive electric power from the one or more power converters 352 and may distribute the electric power to one or more electric power loads of the engine and the aircraft, e.g., in response to one or more commands or other data inputs. Collectively, the second electric machine 310 and the second power electronics assembly 312 may act or serve as a second heat source 356 for providing thermal energy to the coolant fluid as it passes through the second electric power system leg 314C of the thermal management system 300.

Of course, in other embodiments, the directional flow of electric power may be reversed. It will be appreciated that the PDMU(s) 354 may include a computing device(s) configured in substantially the same manner as the exemplary computing devices of the computing system 700 described below with reference to FIG. 7. In such a manner, the PDMU(s) 354 may be configured to receive one or more data inputs and may make control decisions in response to the one or more data inputs.

In exemplary embodiments, as shown in FIG. 3, the thermal management system 300 may be electronically connected to the controller 46. As previously described herein, the controller 46 may be configured to control the power electronics to distribute electrical power between the various components of the hybrid-electric propulsion system 42 (FIGS. 1 and 2). For example, the controller 46 may control the power electronics of the power bus 48 (FIG. 1) to provide electrical power to, or draw electrical power from, the various components, such as the first electric machine 306 and the second electric machine 310, to operate the hybrid-electric propulsion system 42 between various operating modes and perform various functions.

In exemplary embodiments, as shown in FIG. 3, the controller 46 may be electronically coupled to and configured to monitor various operating conditions or parameters of the first heat source 350 and the second heat source 356. For example, sensors 358A, 358B, and 358C, such as but not limited to, temperature sensors, may be coupled to one or more components of the first heat source 350 (e.g., the first electric machine 306 and the first power electronics assembly 308 including but not limited to the power converter 346 and the PDMU(s) 348). In addition, or in the alternative, sensors 358D, 358E, and 358F, such but not limited to, temperature sensors, may be electronically coupled to one or more components of the second heat source 356 (e.g., the second electric machine 310 and the second power electronics assembly 312 including but not limited to the power converter 352 and the PDMU(s) 354). Sensors 358A, 358B, 358C, 358D, 358E, 358F may provide feedback loops to controller 46 to set total flow and flow splits between the first electric power system leg 314B and the second electric power system leg 314C of the closed-loop fluid circuit 314 via at least one of the valve controller 344, the flow control device 304, the pump controller 334, or the fluid pump 328.

In operation, each sensor 358A, 358B, 358C, 358D, 358E, and 358F, will provide a temperature readings to the controller 46. In response, the controller 46 will compare an absolute value trend vs a predetermined value trend limit. If the value trend is approaching the predetermined value trend limit, then the controller 46 will determine whether the thermal management system 300 as a whole or if the first electric power system leg 314B and the second electric power system leg 314C needs more or less coolant fluid flow. Once the determination has been made, the controller 46 may instruct the pump controller 334 to adjust pump speed. In addition or in the alternative, the controller 46 may instruct the valve controller 344 to adjust a flow split at the flow control device 304 to send more/less of the coolant fluid to either or both of the first electric power system leg 314B and the second electric power system leg 314C of the closed-loop fluid circuit 314.

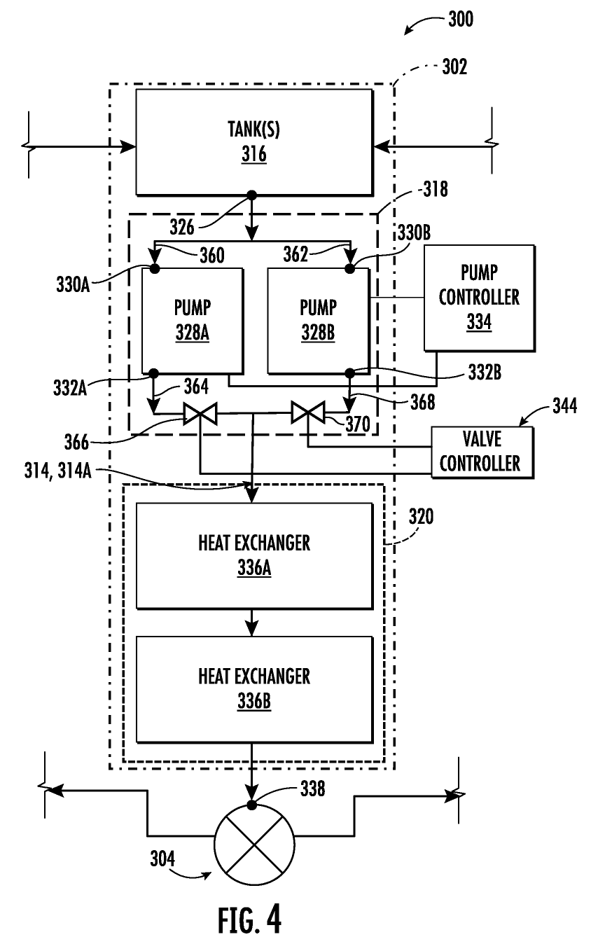

FIG. 4 provides a simplified, schematic view of a portion of the thermal management system 300 as shown in FIG. 3, including the coolant supply system 302, the flow control device 304, the valve controller 344, and the pump controller 334 according to an exemplary embodiment of the present disclosure. As shown in FIG. 4, coolant supply system 302, particularly the coolant supply leg 314A of the closed-loop fluid circuit 314, provides for fluid flow of the coolant fluid from the coolant tank 316 to the flow control device 304, and provides for heat removal from the coolant fluid via the heat exchanger assembly 320.

As shown in FIG. 4, the coolant supply system 302, more particularly, the pump assembly 318, may include a first fluid pump 328A and a second fluid pump 328B arranged in parallel along the coolant supply leg 314A of the closed-loop fluid circuit 314. The pump assembly 318, particularly the first fluid pump 328A and the second fluid pump 328B, may be electronically coupled to the pump controller 334. The pump controller 334 may be configured to control flowrate of the coolant fluid, via the first fluid pump 328A and the second fluid pump 328B, through the closed-loop fluid circuit 314 and to the valve inlet 338 of the flow control device 304. It is to be appreciated that the first heat exchanger 336A and the second heat exchanger 336B may be arranged in series or serial flow order as shown in FIG. 3 and FIG. 4, or in the alternative, may be arranged in parallel as shown in FIG. 6 which is discussed in detail below.

As shown in FIG. 4, the first fluid pump 328A includes a first pump inlet 330A and a first pump outlet 332A. The second fluid pump 328B includes a second pump inlet 330B and a second pump outlet 332B. The first pump inlet 330A is fluidly connected to the tank outlet 326 of the coolant tank 316 via a first supply line 360 of the coolant supply leg 314A. The second pump inlet 330B is fluidly connected to the tank outlet 326 via a second supply line 362 of the coolant supply leg 314A.

The first pump outlet 332A is fluidly connected to the valve inlet 338 of the flow control device 304 via a first return line 364 of the coolant supply leg 314A. In an exemplary embodiment, a first check valve 366 is fluidly coupled to the first return line 364 to prevent backflow into the first fluid pump 328A from the second fluid pump 328B or the coolant supply leg 314A of the closed-loop fluid circuit 314. The second pump outlet 332B is fluidly connected to the valve inlet 338 via a second return line 368 of the coolant supply leg 314A. In an exemplary embodiment, a second check valve 370 is fluidly coupled to the second return line 368 to prevent backflow into the second fluid pump 328B from the first fluid pump 328A or the coolant supply leg 314A of the closed-loop fluid circuit 314. In exemplary embodiments, at least one or both of the first check valve 366 and the second check valve 370 may be passive valves, or at least one or both of the first check valve 366 and the second check valve 370 may be operably connected to the valve controller 344.

In this embodiment, the first fluid pump 328A and the second fluid pump 328B may be operated simultaneously to provide coolant flow to the closed-loop fluid circuit 314 of the thermal management system 300. In case of a pump failure of either the first fluid pump 328A or the second fluid pump 328B, the remaining operational pump may provide an uninterrupted coolant flow to the closed-loop fluid circuit 314. For example, both the first fluid pump 328A and the second fluid pump 328B may be configured to supply roughly 50-50 flow to the to the closed-loop fluid circuit 314. In exemplary embodiments, each of the first fluid pump 328A and the second fluid pump 328B may be sized and configured to independently supply 100% of the coolant flow to the to the closed-loop fluid circuit 314 if necessary. As such, the first fluid pump 328A and the second fluid pump 328B may effectively function interchangeably with respect to one another. In another embodiment, either the first fluid pump 328A or the second fluid pump 328B may be operated as a primary fluid pump with the other fluid pump maintained offline as a backup in case of a pump failure. In other configurations, the first fluid pump 328A and the second fluid pump 328B may be alternated every other flight.

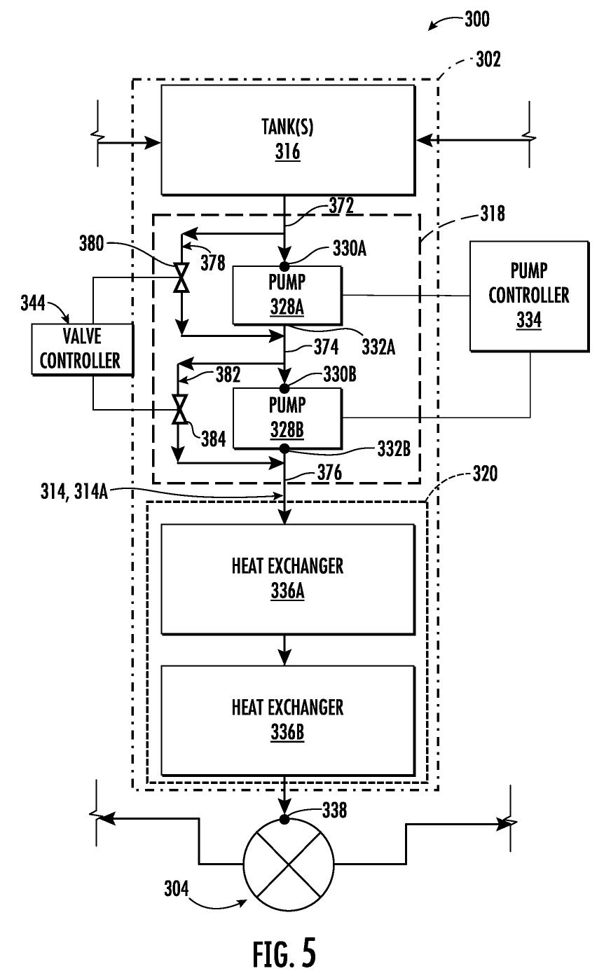

FIG. 5 provides a simplified, schematic view of a portion of the thermal management system 300 as shown in FIG. 3, including the coolant supply system 302, the flow control device 304, the valve controller 344, and the pump controller 334 according to an exemplary embodiment of the present disclosure. As shown in FIG. 5, and similar to FIG. 3 and FIG. 4, coolant supply system 302, particularly the coolant supply leg 314A of the closed-loop fluid circuit 314, provides for fluid flow of the coolant fluid from the coolant tank 316, through the heat exchanger assembly 320, to the valve inlet 338 of the flow control device 304, and provides for heat removal from the coolant fluid via the heat exchanger assembly 320.

As shown in FIG. 5, the coolant supply system 302, more particularly, the pump assembly 318, may include first fluid pump 328A and second fluid pump 328B arranged in series or serial flow order along the coolant supply leg 314A of the closed-loop fluid circuit 314. The pump assembly 318, particularly the first fluid pump 328A and the second fluid pump 328B, may be electronically/operably coupled to the pump controller 334. The pump controller 334 may be configured to control flowrate of the coolant fluid, via one or both of the first fluid pump 328A and the second fluid pump 328B, to the valve inlet 338 of the flow control device 304 and through the closed-loop fluid circuit 314. It is to be appreciated that the first heat exchanger 336A and the second heat exchanger 336B may be arranged in series or serial flow order as shown in FIG. 3, FIG. 4, and FIG. 5, or in the alternative, may be arranged in parallel as shown in FIG. 6, which is discussed in detail below.

As shown in FIG. 5, the first fluid pump 328A includes first pump inlet 330A and first pump outlet 332A. The second fluid pump 328B includes second pump inlet 330B and second pump outlet 332B. The first pump inlet 330A is fluidly connected to the tank outlet 326 of the coolant tank 316 via a first supply line 372 of the coolant supply leg 314A. The second pump inlet 330B is fluidly connected to the first pump outlet 332A via a second supply line 374 of the coolant supply leg 314A. The second pump outlet 332B is fluidly connected to the valve inlet 338 of the flow control device 304 via a third supply line 376 of the coolant supply leg 314A.

In the exemplary embodiment of FIG. 5, the pump assembly 318 includes a first pump bypass circuit 378 having a first bypass valve 380, and a second pump bypass circuit 382 having a second bypass valve 384. The first pump bypass circuit 378 defines a first bypass flowpath extending from the first supply line 372 to the second supply line 374. The second pump bypass circuit 382 defines a second bypass flowpath extending from the second supply line 374 to the third supply line 376. The first bypass valve 380 is fluidly coupled to the first pump bypass circuit 378 and may be configured to actuate between a fully open flow position, partially open flow position, and a fully closed flow position depending on an operational state of one or more of the first fluid pump 328A, the second fluid pump 328B, or an overall operational state of the thermal management system 300. The second bypass valve 384 is fluidly coupled to the second pump bypass circuit 382 and may be configured to actuate between a fully open flow position, a partially open flow position, and a fully closed flow position depending on an operational state of one or more of the first fluid pump 328A, the second fluid pump 328B, or an overall operational state of the thermal management system 300. Either or both of the first bypass valve 380 and the second bypass valve 384 may be passively controlled or may be electronically connected to and controlled by a controller such as the valve controller 344.

In either of the embodiments shown in FIGS. 4 and 5, the first fluid pump 328A and the second fluid pump 328B may be operated simultaneously to provide coolant flow to the closed-loop fluid circuit 314 of the thermal management system 300. In case of a pump failure of either the first fluid pump 328A or the second fluid pump 328B, the remaining operational pump may provide 100% of an uninterrupted coolant flow to the closed-loop fluid circuit 314. For example, both the first fluid pump 328A and the second fluid pump 328B may be configured to supply roughly 50-50 flow to the to the closed-loop fluid circuit 314 when both pumps are operational. In exemplary embodiments, each of the first fluid pump 328A and the second fluid pump 328B may be sized and configured to independently supply 100% of the coolant flow to the to the closed-loop fluid circuit 314 if necessary. As such, the first fluid pump 328A and the second fluid pump 328B may effectively function interchangeably with respect to one another. In another embodiment, either the first fluid pump 328A or the second fluid pump 328B may be operated as a primary fluid pump with the other fluid pump maintained offline as a backup in case of a pump failure. In other configurations, the first fluid pump 328A and the second fluid pump 328B may be alternated every other flight.

FIG. 6 provides a schematic view of another embodiment of the thermal management system 300 shown in FIG. 3, in accordance with an exemplary aspect of the present disclosure. The thermal management system 300 of FIG. 6 may be incorporated into one or more of the gas turbine engines 110A, 110B and/or aircraft 10 described herein, or in any other suitable engine and/or aircraft.

In the embodiment shown in FIG. 6, thermal management system 300 generally includes the coolant supply system 302, a first flow control device 304A, a second flow control device 304B, first heat source 350, second heat source 356, and valve controller 344. The thermal management system 300 further includes the closed-loop fluid circuit 314 including the coolant supply leg 314A, the first electric power system leg 314B, and the second electric power system leg 314C.

The first flow control device 304A is disposed along/fluidly connected to the first electric power system leg 314B between the first heat source 350 and the pump inlet 330. The second flow control device 304B is disposed along/fluidly connected to the second electric power system leg 314C between the second heat source 356 and the pump inlet 330.

The first flow control device 304A may include a valve such as a multi-way valve or flow splitter, as shown in FIG. 3, or may include a check valve or any other valve suitable for controlling flow through the closed-loop fluid circuit 314. The first flow control device 304A is fluidly coupled to the first tank inlet 322 via the first electric power system leg 314B of the closed-loop fluid circuit 314. The second flow control device 304B may include a valve such as a multi-way valve or flow splitter, as shown in FIG. 3, or may include a check valve or any other valve suitable for controlling flow through the closed-loop fluid circuit 314. The second flow control device 304B is fluidly coupled to the pump inlet 330 via the second electric power system leg 314C of the closed-loop fluid circuit 314. In this configuration, the coolant supply leg 314A, the first electric power system leg 314B, the first flow control device 304A, and the second electric power system leg 314C and the second flow control device 304B form a closed-loop or recirculating closed-loop fluid circuit 314.

In exemplary embodiments, the first flow control device 304A and the second flow control device 304B are electronically and operably connected to valve controller 344. The valve controller 344 may be configured to control flowrate of the coolant fluid flowing through the closed-loop fluid circuit 314.

The first heat source 350 generally includes the first electric machine 306, and the first power electronics assembly 308. The first power electronics assembly 308 may include the power converter 346 and the PDMU(s) 348. The second heat source 356 generally includes the second electric machine 310, and the second power electronics assembly 312. The second power electronics assembly 312 may include the power converter 352 and the PDMU(s) 354.

The first electric machine 306 is thermally connected to and in thermal communication with the coolant fluid via the first electric power system leg 314B of the closed-loop fluid circuit 314. The first electric machine 306 may be rotatable with a first rotating component of an engine when the thermal management system 300 is integrated with the engine. For example, in certain exemplary embodiments, the first electric machine 306 may be an electric machine rotatable with the high-speed spool 153 of the gas turbine engine 110A shown in FIG. 2. The first electric machine 306 can be an electric generator, an electric motor, or a combination generator/motor. For this embodiment, the first electric machine 306 is a combination generator/motor. In this manner, when operating as an electric generator, the first electric machine 306 can generate electrical power when driven by the gas turbine engine 110A. When operating as an electric motor, the first electric machine 306 can drive or motor the gas turbine engine 110A.

Referring still to FIG. 6, the first power electronics assembly 308 is electrically connected to the first electric machine 306. The first power electronics assembly 308 is thermally connected to and in thermal communication with the first electric power system leg 314B of the closed-loop fluid circuit 314. In exemplary embodiments, the first power electronics assembly 308 may comprise the power electronics assembly 58 incorporated into one or more of the gas turbine engines 110A, 110B, aircraft 10, or both (FIGS. 1 and 2).

The first power electronics assembly 308 may comprise one or more power converters 346 and one or more high-pressure side power controllers, and more specifically, one or more PDMU(s) 348, in electric connection with the one or more power converters 346, as well as with one or more electric power loads, electric power sources, or both (e.g., of the engine or the aircraft, or both). In such a manner, the one or more PDMU(s) 348 may receive electric power from the one or more power converters 346 and may distribute the electric power to one or more electric power loads of the engine and the aircraft, e.g., in response to one or more commands or other data inputs. Collectively, the first electric machine 306 and the first power electronics assembly 308 may act or serve as the first heat source 350 for providing thermal energy or heat to the coolant fluid flowing through the first electric power system leg 314B of the thermal management system 300.

Of course, in other embodiments, the directional flow of electric power may be reversed. It will be appreciated that the PDMU(s) 348 may include a computing device(s) configured in substantially the same manner as the exemplary computing devices of the computing system 700 described below with reference to FIG. 7. In such a manner, the PDMU(s) 348 may be configured to receive one or more data inputs and may make control decisions in response to the one or more data inputs.

As further illustrated in FIG. 6, the second electric machine 310 is thermally connected to and in thermal communication with the coolant fluid via the second electric power system leg 314C of the closed-loop fluid circuit 314. The second electric machine 310 may be rotatable with a second rotating component of an engine when the thermal management system 300 is integrated with the engine. For example, in certain exemplary embodiments, the second electric machine 310 may be a low-pressure electric machine rotatable with the low-speed spool 155 of the gas turbine engine 110A shown in FIG. 2. The second electric machine 310 can be an electric generator, an electric motor, or a combination generator/motor. For this embodiment, the second electric machine 310 is a combination generator/motor. In this manner, when operating as an electric generator, the second electric machine 310 can generate electrical power when driven by the gas turbine engine 110A. When operating as an electric motor, the second electric machine 310 can drive or motor the gas turbine engine 110A.

Referring still to FIG. 6, the second power electronics assembly 312 is electrically connected to the second electric machine 310. The second power electronics assembly 312 is thermally connected to and in thermal communication with the second electric power system leg 314C of the closed-loop fluid circuit 314. The second power electronics assembly 312 may be incorporated into one or more of the gas turbine engines 110A, 110B, aircraft 10, or both (FIGS. 1 and 2). The second power electronics assembly 312 may comprise one or more power converters 352 and one or more low-pressure side power controllers, and more specifically, one or more low-pressure power distribution and monitoring units (referred to herein as a “PDMU(s) 354”), in electric connection with the one or more power converters 352, as well as with one or more electric power loads, electric power sources, or both (e.g., of the engine or the aircraft, or both). In such a manner, the one or more PDMU(s) 354 may receive electric power from the one or more power converters 352 and may distribute the electric power to one or more electric power loads of the engine and the aircraft, e.g., in response to one or more commands or other data inputs. Collectively, the second electric machine 310 and the second power electronics assembly 312 may act or serve as a second heat source 356 for providing thermal energy to the coolant fluid as it passes through the second electric power system leg 314C of the thermal management system 300.

Of course, in other embodiments, the directional flow of electric power may be reversed. It will be appreciated that the PDMU(s) 354 may include a computing device(s) configured in substantially the same manner as the exemplary computing devices of the computing system 700 described below with reference to FIG. 7. In such a manner, the PDMU(s) 354 may be configured to receive one or more data inputs and may make control decisions in response to the one or more data inputs.

In exemplary embodiments, as shown in FIG. 6, the thermal management system 300 may be electronically connected to the controller 46. As previously described herein, the controller 46 may be configured to control the power electronics to distribute electrical power between the various components of the hybrid-electric propulsion system 42. For example, the controller 46 may control the power electronics of the power bus 48 (FIG. 1) to provide electrical power to, or draw electrical power from, the various components, such as the first electric machine 306 and the second electric machine 310, to operate the hybrid-electric propulsion system 42 between various operating modes and perform various functions.

In exemplary embodiments, the controller 46 may be electronically coupled to and configured to monitor various operating conditions or parameters of the first heat source 350 and the second heat source 356. For example, sensors 358A, 358B, and 358C, such but not limited to, temperature sensors, may be coupled to one or more components of the first heat source 350 (e.g., the first electric machine 306 and the first power electronics assembly 308 including but not limited to the power converter 346 and the PDMU(s) 348). In addition, or in the alternative, sensors 358D, 358E, and 358F, such as but not limited to, temperature sensors, may be electronically coupled to one or more components of the second heat source 356 (e.g., the second electric machine 310 and the second power electronics assembly 312 including but not limited to the power converter 352 and the PDMU(s) 354). Sensors 358A, 358B, 358C, 358D, 358E, and 358F may provide feedback loops to controller 46 to set total flow and flow splits between the first electric power system leg 314B and the second electric power system leg 314C via at least one of the valve controller 344, the flow control device 304, the pump controller 334, or the fluid pump 328.

In the embodiment shown in FIG. 6, the coolant supply system 302 generally includes pump assembly 318, and heat exchanger assembly 320. The pump assembly 318, the first flow control device 304A and the second flow control device 304B are arranged or disposed along the closed-loop fluid circuit 314. It is to be appreciated that although only one fluid pump 328 is shown in FIG. 6, the pump assembly 318 may include more than one fluid pump as shown in FIGS. 4 and 5. The fluid pump 328 may be an electric pump or a mechanical pump. The pump assembly 318 includes pump inlet 330 and pump outlet 332. The pump assembly 318, particularly the fluid pump 328, may be electronically coupled to pump controller 334. The pump controller 334 may be operably coupled to the controller 46. The pump controller 334 may be configured to control flowrate of the coolant fluid, via the fluid pump 328, through the closed-loop fluid circuit 314.

As further shown in FIG. 6, the coolant tank 316 (FIG. 3) is replaced by two separate coolant tanks. For example, as illustrated in FIG. 6, the thermal management system 300 may include a first coolant tank 386 and a second coolant tank 388. The first coolant tank 386 is disposed along and dedicated exclusively to the first electric power system leg 314B of the closed-loop fluid circuit 314 downstream from the pump outlet 332. In exemplary embodiments, the first coolant tank 386 may be disposed along the first electric power system leg 314B of the closed-loop fluid circuit 314 upstream from an inlet 390 to the first flow control device 304A. The first coolant tank 386 may be configured to receive the coolant fluid from the first electric power system leg 314B, store, and then resupply the coolant fluid back to the coolant supply leg 314A of the closed-loop fluid circuit 314.

The second coolant tank 388 is disposed along and dedicated exclusively to the second electric power system leg 314C of the closed-loop fluid circuit 314 downstream from the pump outlet 332. In exemplary embodiments, the second coolant tank 388 may be disposed along the second electric power system leg 314C of the closed-loop fluid circuit 314 upstream from an inlet 392 to the second flow control device 304B. The second coolant tank 388 may be configured to receive the coolant fluid from the second electric power system leg 314C, store, and then resupply the coolant fluid back to the coolant supply leg 314A of the closed-loop fluid circuit 314.

As shown in FIG. 6, the heat exchanger assembly 320 is disposed downstream from the pump assembly 318, more particularly downstream from the pump outlet 332, upstream from the first flow control device 304A and upstream from the second flow control device 304B. The heat exchanger assembly 320 includes at least one heat exchanger. For example, the embodiment shown in FIG. 6 includes a first heat exchanger 336A and second heat exchanger 336B arranged in parallel to one another.

It is to be appreciated that the heat exchanger assembly 320, particularly the first heat exchanger 336A and the second heat exchanger 336B, may be located in the fan duct 172 (FIG. 2), such as the heat exchanger 191 (FIG. 2), exposed to overboard air, located in within the core cowl 148 (FIG. 2), or elsewhere within the gas turbine engine 110A (FIGS. 1 and 2). The first heat exchanger 336A and the second heat exchanger 336B could be gas-gas, gas-liquid, liquid-liquid heat exchangers or thermoelectric devices. Heat sink fluid associated with the first heat exchanger 336A and the second heat exchanger 336B could be fuel, water, water from an aircraft lavatory system, refrigerant from an environmental control system of an aircraft, or other suitable thermal transfer fluid.

The first heat exchanger 336A and the second heat exchanger 336B are each in thermal communication with (or thermally connected to) the coolant fluid via the coolant supply leg 314A of the closed-loop fluid circuit 314. For example, as shown in FIG. 6, the coolant supply leg 314A may split downstream from the pump outlet 332 into a first heat exchanger leg 394 and a second heat exchanger leg 396. The first heat exchanger leg 394 extends through and is thermally coupled to the first heat exchanger 336A and fluidly couples the coolant supply leg 314A to the first electric power system leg 314B. The second heat exchanger leg 396 extends through and is thermally coupled to the second heat exchanger 336B and fluidly couples the coolant supply leg 314A to the second electric power system leg 314C. In exemplary embodiments, a jumper line 398, disposed post or downstream from the first heat exchanger 336A and the second heat exchanger 336B may provide a fluid connection between the first heat exchanger leg 394 and the second heat exchanger leg 396 of the coolant supply leg 314A. In an exemplary embodiment, a valve 400 may be disposed along/fluidly coupled to the jumper line 398. The valve 400 may be configured to control flow of the coolant between the first heat exchanger leg 394 and the second heat exchanger leg 396 of the coolant supply leg 314A.

In particular embodiments, as shown in FIG. 6, the heat exchanger assembly 320 may further comprise a third heat exchanger 336C arranged in series with the first heat exchanger 336A along the first heat exchanger leg 394 of the coolant supply leg 314A of the closed-loop fluid circuit 314. In addition, or in the alternative, the heat exchanger assembly 320 may further comprise a fourth heat exchanger 336D arranged in series with the second heat exchanger 336B along the second heat exchanger leg 396 of the coolant supply leg 314A of the closed-loop fluid circuit 314. The third heat exchanger 336C and the fourth heat exchanger 336D could be gas-gas, gas-liquid, liquid-liquid heat exchangers or thermoelectric devices. Heat sink fluid associated with the third heat exchanger 336C and the fourth heat exchanger 336D could be fuel, water, water from an aircraft lavatory system, refrigerant from an environmental control system of an aircraft, or other suitable thermal transfer fluid.

If during operation of the hybrid electric aircraft engine one of the first coolant tank 386 or any portion of the first electric power system leg 314B or the second coolant tank 388 or any portion of the second electric power system leg 314C fails or otherwise becomes inoperable (e.g. clogs, or leaks, etc.), the first flow control device 304A and the second flow control device 304B may be manipulated or actuated by the valve controller 344 to provide a means to cut off flow to the second electric power system leg 314C or the second electric power system leg 314C respectively. This embodiment prevents total shut-down of the thermal management system in case of a single failed component.

FIG. 7 provides an example computing system 700 according to example embodiments of the present disclosure. The computing devices or elements described herein, such as controller 46, pump controller 334, valve controller 344, PDMU(s) 348 and PDMUs 354, may include various components and perform various functions of the computing system 700 described below, for example.

As shown in FIG. 7, the computing system 700 can include one or more computing device(s) 702. The computing device(s) 702 can include one or more processor(s) 702A and one or more memory device(s) 702B. The one or more processor(s) 702A can include any suitable processing device, such as a microprocessor, microcontroller, integrated circuit, logic device, and/or other suitable processing device. The one or more memory device(s) 702B can include one or more computer-executable or computer-readable media, including, but not limited to, non-transitory computer-readable media, RAM, ROM, hard drives, flash drives, and/or other memory devices.

The one or more memory device(s) 702B can store information accessible by the one or more processor(s) 702A, including computer-readable instructions 702C that can be executed by the one or more processor(s) 702A. The computer-readable instructions 702C can be any set of instructions that when executed by the one or more processor(s) 702A, cause the one or more processor(s) 702A to perform operations. In some embodiments, the computer-readable instructions 702C can be executed by the one or more processor(s) 702A to cause the one or more processor(s) 702A to perform operations, such as any of the operations and functions for which the computing system 700 and/or the computing device(s) 702 are configured, such as controlling operation of electrical power systems or the power electronics assemblies, the electric machines, and the one or more flow control devices. The computer-readable instructions 702C can be software written in any suitable programming language or can be implemented in hardware. Additionally, and/or alternatively, the computer-readable instructions 702C can be executed in logically and/or virtually separate threads on processor(s) 702A. The memory device(s) 702B can further store data that can be accessed by the processor(s) 702A. For example, stored data 702D can include models, lookup tables, databases, graphs, etc.

The computing device(s) 702 can also include a network interface 702E used to communicate, for example, with the other components of the computing system 700 (e.g., via a communication network). The network interface 702E can include any suitable components for interfacing with one or more network(s), including for example, transmitters, receivers, ports, controllers, antennas, and/or other suitable components. One or more devices can be configured to receive one or more commands from the computing device(s) 702 or provide one or more commands to the computing device(s) 702.

The technology discussed herein makes reference to computer-based systems and actions taken by and information sent to and from computer-based systems. One of ordinary skill in the art will recognize that the inherent flexibility of computer-based systems allows for a great variety of possible configurations, combinations, and divisions of tasks and functionality between and among components. For instance, processes discussed herein can be implemented using a single computing device or multiple computing devices working in combination. Databases, memory, instructions, and applications can be implemented on a single system or distributed across multiple systems. Distributed components can operate sequentially or in parallel.

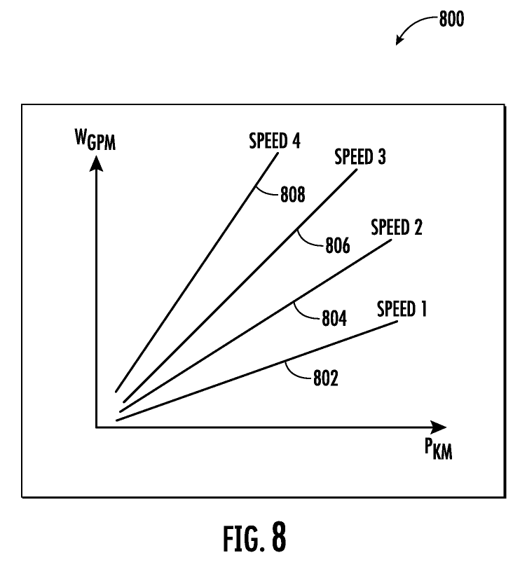

FIG. 8 provides an exemplary graph 800 illustrating a relationship between a desired or required coolant flowrate (y-axis) as measured in gallons per-minute and labeled as (W_{GPM}) needed to sufficiently cool a respective electronic component associated with the first electric power system leg 314B or the second electric power system leg 314C as a function of power need or demand (x-axis) as measured in kilowatts and labeled as (P_{kW}). FIG. 8 further illustrates individual predefined curves 802, 804, 806, and 808 representing a relationship between power need P_{kW} and required coolant flowrate W_{GPM} at a particular rotational shaft speed such as that of the high-pressure shaft or the low-pressure shaft of the gas turbine engine 110A (FIG. 2) for an exemplary electronic component a respective electronic component associated with the first electric power system leg 314B or the second electric power system leg 314C. Individual predefined curves may be different for each respective electronic component associated with the first electric power system leg 314B and for each respective electronic component associated with the second electric power system leg 314C.

In particular embodiments, the controller 46 may be programmed to include a set of predefined curves, (e.g. 802, 804, 806, and 808), for each respective electronic component associated with the first electric power system leg 314B and a set of predefined curves for each respective electronic component associated with the second electric power system leg 314C. In operation, the controller 46 is configured to receive signals or data from various sensors indicative of high-pressure shaft speed, current power output from each respective electronic component associated with the first electric power system leg 314B, low-pressure shaft speed and current power output of each respective electronic component associated with the second electric power system leg 314C. The controller 46 is further configured to determine a required cooling flow for each respective electronic component of the first electric power system leg 314B and a required cooling flow for each respective electronic component of the second electric power system leg 314C based on the received signals or data and the respective predefined curves.

Because each respective electronic component associated with the first electric power system leg 314B will have a different set of predefined curves, the controller 46 will select the most demanding predefined curve (that is the predefined curve having the highest coolant flow requirement) to set the overall required cooling flow for the first electric power system leg 314B leg. Similarly, because each respective electronic component associated with the second electric power system leg 314C will have a different set of predefined curves, the controller 46 will select the most demanding predefined curve (that is the predefined curve having the highest coolant flow requirement) to set the overall required cooling flow for the second electric power system leg 314C.

Once the overall coolant flowrate for each of first electric power system leg 314B and the second electric power system leg 314C leg have been determined by the controller 46, the controller will then determine the total coolant flowrate required to sufficiently cool both the first electric power system leg 314B and the second electric power system leg 314C simultaneously and then send a signal to the pump controller 334 to set the pump speed to achieve the total coolant flowrate to the thermal management system 300. In addition, the controller 46 will send a signal to the valve controller 344 to actuate or otherwise manipulate the flow control device(s) 104, 104A, 104B to split the coolant flow from the coolant supply leg 314A to meet the individual coolant flow requirements for first electric power system leg 314B and the second electric power system leg 314C.

The present disclosure provides a thermal management system tailored to meet the thermal needs of both the first heat source 350 and the second heat source 356. The present disclosure provides a singular coolant supply system 302 dedicated to providing coolant fluid to both the first electric power system leg 314B and the second electric power system leg 314C simultaneously, or in the alternative, to meter or control flowrates of the coolant fluid individually to each of the first electric power system leg 314B and the second electric power system leg 314C to accommodate thermal management needs at particular operating conditions of the gas turbine engine 110A, or to accommodate for system failures of either or both of the first electric power system leg 314B and the second electric power system leg 314C of the thermal management system 300. In exemplary embodiments, the thermal management system 300 is separate from other engine cooling loops.

Further aspects are provided by the subject matter of the following clauses:

A thermal management system, comprising: a closed-loop fluid circuit including a coolant supply leg, a first electric power system leg, and a second electric power system leg; a coolant supply system fluidly coupled to the coolant supply leg for providing a coolant fluid to the coolant supply leg, the first electric power system leg, and the second electric power system leg of the closed-loop fluid circuit; a flow control device having an inlet fluidly coupled to the coolant supply system via the coolant supply leg, a first outlet fluidly coupled to the first electric power system leg, and a second outlet fluidly coupled to the second electric power system leg; a first heat source in thermal communication with the coolant fluid via the first electric power system leg; and a second heat source in thermal communication with the coolant fluid via the second electric power system leg.

The thermal management system of the preceding or any following clause, wherein the coolant supply system comprises a coolant tank, a pump assembly, and a heat exchanger assembly disposed upstream from the inlet of the flow control device.

The thermal management system of any preceding or following clause, wherein the coolant supply system comprises a pump assembly, wherein the pump assembly includes a first fluid pump and a second fluid pump.

The thermal management system of any preceding or following clause, wherein the first fluid pump and the second fluid pump are arranged in serial flow order.

The thermal management system of any preceding or following clause, wherein the pump assembly further comprises a first pump bypass circuit configured to bypass the first fluid pump, and a second pump bypass circuit configured to bypass the second fluid pump.

The thermal management system of any preceding or following clause, wherein the first fluid pump and the second fluid pump are arranged in parallel to one another along the coolant supply leg of the closed-loop fluid circuit.

The thermal management system of any preceding or following clause, wherein the heat exchanger assembly comprises a first heat exchanger and a second heat exchanger.

The thermal management system of any preceding or following clause, wherein the first heat exchanger and the second heat exchanger are arranged in series along the coolant supply leg of the closed-loop fluid circuit.

The thermal management system of any preceding or following clause, wherein the first heat exchanger and the second heat exchanger are arranged in parallel along the coolant supply leg of the closed-loop fluid circuit.

The thermal management system of any preceding or following clause, wherein the heat exchanger assembly further comprises a third heat exchanger arranged in series with the first heat exchanger along the coolant supply leg, and a fourth heat exchanger arranged in series with the second heat exchanger along the coolant supply leg.

The thermal management system of any preceding or following clause, further comprising a valve controller operably connected to the flow control device.

The thermal management system of any preceding or following clause, further comprising a first sensor operably connected to the first heat source and to the valve controller, and a second sensor operably connected to the second heat source and to the valve controller, wherein the valve controller is configured to control flowrate through the flow control device based on inputs provided to the valve controller from the first sensor and the second sensor.

The thermal management system of any preceding or following clause, wherein the first heat source includes a first electric machine and a first power electronics assembly, and wherein the second heat source includes a second electric machine and a second power electronics assembly.

The thermal management system of any preceding or following clause, wherein the first power electronics assembly includes at least one of a first converter and a first power distribution and monitoring unit.

The thermal management system of any preceding or following clause, wherein the second power electronics assembly includes at least one of a second power converter and a second power distribution and monitoring unit.

The thermal management system of any preceding or following clause, wherein at least one of the first electric machine and the second electric machine is operably coupled to a propulsor of an aeronautical hybrid-electric propulsion machine.

A thermal management system, comprising: a closed-loop fluid circuit including a coolant supply leg, a first electric power system leg, and a second electric power system leg; a coolant supply system fluidly coupled to the coolant supply leg for providing a coolant fluid to the coolant supply leg, the first electric power system leg, and the second electric power system leg of the closed-loop fluid circuit; a first heat source in thermal communication with the coolant fluid via the first electric power system leg; a first flow control device fluidly coupled to the first electric power system leg downstream from the first heat source and upstream from the coolant supply system; a second heat source in thermal communication with the coolant fluid via the second electric power system leg; and a second flow control device fluidly coupled to the second electric power system leg downstream from the second heat source and upstream from the coolant supply system.

The thermal management system of the preceding or any following clause, further comprising a first coolant tank and a second coolant tank.

The thermal management system of any preceding or following clause, further comprising a valve controller operably connected to the first flow control device and the second flow control device.

The thermal management system of any preceding or following clause, further comprising a first sensor operably connected to the first heat source and to the valve controller, and a second sensor operably connected to the second heat source and to the valve controller, wherein the valve controller is configured to control flowrate through the flow control device based on inputs provided to the valve controller from the first sensor and the second sensor.

This written description uses examples to disclose the present disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

WE CLAIM:

1. A thermal management system, comprising:
a closed-loop fluid circuit including a coolant supply leg, a first electric power system leg, and a second electric power system leg;
a coolant supply system fluidly coupled to the coolant supply leg for providing a coolant fluid to the coolant supply leg, the first electric power system leg, and the second electric power system leg of the closed-loop fluid circuit;
a flow control device having an inlet fluidly coupled to the coolant supply system via the coolant supply leg, a first outlet fluidly coupled to the first electric power system leg, and a second outlet fluidly coupled to the second electric power system leg;
a first heat source in thermal communication with the coolant fluid via the first electric power system leg; and
a second heat source in thermal communication with the coolant fluid via the second electric power system leg.

2. The thermal management system of claim 1, wherein the coolant supply system comprises a coolant tank, a pump assembly, and a heat exchanger assembly disposed upstream from the inlet of the flow control device.

3. The thermal management system of claim 1, wherein the coolant supply system comprises a pump assembly, wherein the pump assembly includes a first fluid pump and a second fluid pump.

4. The thermal management system of claim 3, wherein the first fluid pump and the second fluid pump are arranged in serial flow order.

5. The thermal management system of claim 4, wherein the pump assembly further comprises a first pump bypass circuit configured to bypass the first fluid pump, and a second pump bypass circuit configured to bypass the second fluid pump.

6. The thermal management system of claim 3, wherein the first fluid pump and the second fluid pump are arranged in parallel to one another along the coolant supply leg of the closed-loop fluid circuit.

7. The thermal management system of claim 2, wherein the heat exchanger assembly comprises a first heat exchanger and a second heat exchanger.

8. The thermal management system of claim 7, wherein the first heat exchanger and the second heat exchanger are arranged in series along the coolant supply leg of the closed-loop fluid circuit.

9. The thermal management system of claim 7, wherein the first heat exchanger and the second heat exchanger are arranged in parallel along the coolant supply leg of the closed-loop fluid circuit.

10. The thermal management system of claim 9, wherein the heat exchanger assembly further comprises a third heat exchanger arranged in series with the first heat exchanger along the coolant supply leg, and a fourth heat exchanger arranged in series with the second heat exchanger along the coolant supply leg.

11. The thermal management system of claim 1, further comprising a valve controller operably connected to the flow control device.

12. The thermal management system of claim 11, further comprising a first sensor operably connected to the first heat source and to the valve controller, and a second sensor operably connected to the second heat source and to the valve controller, wherein the valve controller is configured to control flowrate through the flow control device based on inputs provided to the valve controller from the first sensor and the second sensor.

13. The thermal management system of claim 1, wherein the first heat source includes a first electric machine and a first power electronics assembly, and wherein the second heat source includes a second electric machine and a second power electronics assembly.

14. The thermal management system of claim 13, wherein the first power electronics assembly includes at least one of a first power converter and a first power distribution and monitoring unit.

15. The thermal management system of claim 13, wherein the second power electronics assembly includes at least one of a second power converter and a second power distribution and monitoring unit.

16. The thermal management system of claim 13, wherein at least one of the first electric machine and the second electric machine is operably coupled to a propulsor of an aeronautical hybrid-electric propulsion machine.

17. A thermal management system, comprising:
a closed-loop fluid circuit including a coolant supply leg, a first electric power system leg, and a second electric power system leg;
a coolant supply system fluidly coupled to the coolant supply leg for providing a coolant fluid to the coolant supply leg, the first electric power system leg, and the second electric power system leg of the closed-loop fluid circuit;
a first heat source in thermal communication with the coolant fluid via the first electric power system leg;
a first flow control device fluidly coupled to the first electric power system leg downstream from the first heat source and upstream from the coolant supply system;
a second heat source in thermal communication with the coolant fluid via the second electric power system leg; and
a second flow control device fluidly coupled to the second electric power system leg downstream from the second heat source and upstream from the coolant supply system.

18. The thermal management system of claim 17, further comprising a first coolant tank and a second coolant tank.

19. The thermal management system of claim 17, further comprising a valve controller operably connected to the first flow control device and the second flow control device.

20. The thermal management system of claim 19, further comprising a first sensor operably connected to the first heat source and to the valve controller, and a second sensor operably connected to the second heat source and to the valve controller, wherein the valve controller is configured to control flowrate through the first flow control device and the second flow control device based on inputs provided to the valve controller from the first sensor and the second sensor.
